(19) United States
(12) Patent Application Publication
(10) Pub. No.: US 2025/0364634 A1
(43) Pub. Date: Nov. 27, 2025

(54) ORGANIC HEAT TRANSFER SYSTEM, METHOD, AND FLUID

(71) Applicant: The Lubrizol Corporation, Wickliffe, OH (US)

(72) Inventors: Anil Agiral, Pepper Pike, OH (US); Andrew J. Richenderfer, Akron, OH (US); William D. Abraham, Concord Township, OH (US); Amy L. Short, Lakewood, OH (US); Christopher F. McFadden, Kirtland, OH (US); Timothy R. Smith, Belper (GB); Gareth Brown, Belper (GB); Megan Browning, Concord Township, OH (US); John R. Johnson, Bainbridge Township, OH (US); Paige Rockwell, Mentor on the Lake, OH (US)

(73) Assignee: The Lubrizol Corporation, Wickliffe, OH (US)

(21) Appl. No.: 18/857,219

(22) PCT Filed: Apr. 18, 2023
(86) PCT No.: PCT/US2023/018905

§ 371 Date: Oct. 16, 2024

Related U.S. Application Data
(60) Provisional application No. 63/332,503, filed on Apr. 19, 2022.

(51) Int. Cl. H01M 10/6569; C09K 5/10; H01M 10/613; H01M 10/625; H05K 7/20

(52) U.S. Cl. CPC H01M 10/6569; C09K 5/10; H01M 10/613; H01M 10/625; H05K 7/203; H05K 7/20809; H05K 7/20881

(57) ABSTRACT

The disclosed technology relates to a heat transfer fluid and a heat transfer system and heat transfer method employing the heat transfer fluid. In particular, the technology relates to a heat transfer fluid containing a heat transfer additive, such as, for example, phase change material and/or halogenated hydrocarbon.

### BACKGROUND OF THE INVENTION

The disclosed technology relates to a heat transfer fluid and a heat transfer system and heat transfer method employing the heat transfer fluid. In particular, the technology relates to a heat transfer fluid containing a heat transfer additive, such as, for example, phase change material and/or halogenated hydrocarbon.

The operation of a power source generates heat. A heat transfer system, in communication with the power source, regulates the generated heat, and ensures that the power source operates at an optimum temperature. The heat transfer system generally comprises a heat transfer fluid that facilitates absorbing and dissipating the heat from the power source. Traditional heat transfer fluids, which generally consist of water and a glycol, and are prone to freezing.

The promise of advanced immersive heat transfer fluids is based on thermally conductive, electrically non-conducting (dielectric) coolant. Although full immersion helps to cut energy consumption and reduce costs, further improvement in heat transfer performance of dielectric coolants is needed given such fluids low thermo-physical properties (density, thermal conductivity, and heat capacity) compared to water cooling.

Thus, a need exists for a heat transfer system and method employing an inexpensive heat transfer fluid with improved heat transfer performance.

### SUMMARY OF THE INVENTION

The disclosed technology, therefore, solves the problem of heat transfer performance and safety concerns in the cooling of electrical componentry by operating the electrical componentry while immersed in a heat transfer fluid containing phase change materials. Phase change material may or may not be in some form of encapsulation. It has surprisingly been found that by completely engulfing some phase change material, in the form of nanodroplets, which are well-dispersed in heat transfer fluid, a highly durable heat transfer system with enhanced heat transfer performance can be realized.

Similarly, enhanced heat transfer performance can be realized from the addition to the heat transfer fluid of a halogenated hydrocarbon.

Provided therefore is a heat transfer fluid containing a hydrocarbon oil and heat transfer additive. In an embodiment, the heat transfer additive can include phase change material. In the same, or different embodiment, the heat transfer additive can include halogenated hydrocarbon.

The method and/or system will be particularly useful in the transfer of heat from battery systems, such as those in an electric vehicle and uninterrupted power supplies, or the transfer of heat from computer electronics, such as those in a server and digital asset mining devices.

The technology also includes a method of lubricating an electrified driveline. The method involves applying the heat transfer fluid to a driveline and operating the driveline.

The technology also includes a method of cooling electrical componentry, such as a computer server. The method involves immersing the electrical componentry in a bath of the heat transfer fluid and operating the electrical componentry.

Also provided herein is an immersion coolant system. The system can be employed, for example, in an electric vehicle or a server farm or data center. The system can include a battery pack, or a computer server situated in a bath that is in fluid contact with a heat transfer fluid reservoir filled with the heat transfer fluid discussed herein.

The method and/or system will also find use for other electrical componentry, such as, for example, in aircraft electronics, other computer electronics, inverters, DC to DC converters, AC to DC converters, chargers, phase change inverters, electric motors, electric motor controllers, and DC to AC inverters.

### DETAILED DESCRIPTION OF THE INVENTION

Various preferred features and embodiments will be described below by way of non-limiting illustration.

The disclosed technology provides a method of cooling electrical componentry by contacting, or immersing, the electrical componentry directly with a composition comprising hydrocarbon (in some cases isoparaffinic) oil and oxygenate and operating the electrical componentry.

Electrical componentry includes any electronics that utilize power and generate thermal energy that must be dissipated to prevent the electronics from overheating. Examples include computer electronics, such as aircraft electronics, computer servers and computer electronics such as microprocessors, and specifically computer hardware employed in cryptocurrency mining, uninterruptable power supplies (UPSs), power electronics (such as IGBTs, SCRs, thyristors, capacitors, diodes, transistors, rectifiers, and the like), energy storage devices, and the like. Electrical componentry also includes batteries as well as power delivery systems such as car charging stations. Further examples include inverters, DC to DC converters, AC to DC converters, chargers, phase change inverters, electric motors, electric motor controllers, and DC to AC inverters.

While several examples of electrical componentry have been provided, the heat transfer fluid may be employed in any assembly or for any electrical componentry to provide an improved heat transfer fluid with cold temperature performance without significantly increasing the electrical conductivity and potential flammability of the mixture.

The method and/or system will be particularly useful in the transfer of heat from battery systems, such as those in an electric vehicle such as an electric car, truck or even electrified mass transit vehicle, like a train or tram. The main piece of electrical componentry in electrified transportation is often battery modules, which may encompass one or more battery cell stacked relative to one another to construct the battery module, which in turn may be stacked together to form a battery pack. Heat may be generated by each battery cell during charging and discharging operations or transferred into the battery cells during key-off conditions of the electrified vehicle as a result of relatively extreme (i.e., hot) ambient conditions. The battery module will therefore include a heat transfer system for thermally managing the battery modules over a full range of ambient and/or operating conditions. In fact, operation of battery modules can occur during the use and draining of the power therefrom, such as in the operation of the battery module, or during the charging of the battery module. The charging system, including the alternator, regulator, charging cables, and fuses may also generate heat and the method and/or system can be employed therewith as well. Regarding charging, the use of the heat transfer fluid can allow the charging of the battery module to at least 75% of the total battery capacity restored in a period of less than 15 minutes.

Similarly, electrical componentry in electrified transportation can include fuel cells, solar cells, solar panels, photovoltaic cells and the like that require cooling by the heat transfer fluid. Such electrified transportation may also include traditional internal combustion engines as, for example, in a hybrid vehicle.

Electrified transportation may also include electric motors as the electrical componentry. Electric motors may be employed anywhere along the driveline of a vehicle to operate, for example, transmissions, axles, and differentials. Such electric motors can be cooled by a heat transfer system employing the heat transfer fluid.

The method may be employed in lubricating a drivetrain, including, for example, an electrified transmission and/or an electric motor.

The method and/or system will also be particularly useful in the transfer of heat from computer electronics, such as computer servers, and other computer electronics. Examples of computer electronics include, but are not limited to, for example, motherboards, circuit boards, chips (CPU, GPU), microprocessors, densely packed servers in data centers, computers in distributed computing clusters, workstations in office buildings, medical imaging devices, electronic communications equipment in cellular networks, solar panels, gaming consoles, personal computers, home appliances, high-power diode laser arrays, light emitting diode (LED) arrays, theater lighting systems, video projectors, directed-energy weapons, solar panels.

The method and/or system can include providing a heat transfer system containing electrical componentry requiring cooling. The heat transfer system will include, among other things, a bath in which the electrical componentry may be situated in a manner that allows the electrical componentry to be in direct fluid contact with the heat transfer fluid. The bath will be in fluid contact with a heat transfer fluid reservoir and a heat exchanger.

The electrical componentry may be operated along with operating the heat transfer system. The heat transfer system may be operated, for example, by circulating the heat transfer fluid through the heat transfer system via pumping or via natural circulation.

For example, the heat transfer system may include means to pump cooled heat transfer fluid from the heat transfer fluid reservoir into the bath, and to pump heated heat transfer fluid out of the bath through the heat exchanger and back into the heat transfer fluid reservoir. In some embodiments, the heat transfer system may employ natural circulation to drive fluid flow. Natural circulation includes flow where the density changes as a result of heat input, driving fluid flow due to gravity. In this manner, while the electrically componentry are operated, the heat transfer system may also be operated to provide cooled heat transfer fluid to the electrical componentry to absorb heat generated by the electrical componentry, and to remove heat transfer fluid that has been heated by the electrical componentry to be sent to the heat exchanger for cooling and recirculation back into the heat transfer fluid reservoir.

Dielectric constant (also called relative permittivity) is an important feature of a heat transfer fluid for an immersion cooling system. To avoid issues with electrical current leakage, the heat transfer fluid into which the electrical componentry is immersed may have a dielectric constant of 5.0 or lower as measured according to ASTM D924. The dielectric constant of the heat transfer fluid at room temperature (i.e., between 2° and 25° C.) can also be less than 4.5, 4.0, 3.0, 2.5, or less than 2.3 or less than 1.9.

The heat transfer fluid can also have a kinematic viscosity measured at 100° C. of at least 0.7 cSt, or at least 0.9 cSt, or at least 1.1 cSt, or from 0.7 to 7.0 cSt, or from 0.9 to 6.5 cSt, or even from 1.1 to 6.0 cSt as measured according to ASTM D445_100. For a given chemical family being pumped at a given power, higher viscosity fluids are typically less effective at removing heat, given higher resistance to flow. The same phenomena also occur for natural convection systems.

Immersion heat transfer fluids need to flow freely at very low temperatures. In one embodiment the heat transfer fluid has a pour point of at least −10° C., or at least −25° C., or at least −30° C., or at least −40° C., or at least −50° C. as measured according to ASTM D5985. In one embodiment, the heat transfer fluid has an absolute viscosity of no more than 900 cP at −30° C., or no more than 500 cP at −30° C., or no more than 100 cP at −30° C. as measured according to ASTM D2983.

The heat transfer fluid contains hydrocarbon (in some cases isoparaffinic) oil and oxygenate.

The hydrocarbon (e.g., isoparaffinic) oil has a flash point of at least 50° C. as measured according to ASTM D92 and or ASTM D93 of at least 60° C., or at least 75° C., or at least 100° C., or at least 150° C., and in some cases at least 200° C. or at least 250° C.

Hydrocarbon oils [including Isoparaffins (or isoparaffinic oils)] are saturated hydrocarbon compounds containing at least one hydrocarbyl branch or at least one saturated 5 or 6 membered hydrocarbyl ring, sufficient to provide fluidity to both very low and high temperatures. Hydrocarbon oils (Isoparaffins) of the invention may include natural and synthetic oils, oil derived from hydrocracking, hydrogenation, and hydrofinishing of refined oils, re-refined oils, or mixtures thereof. Hydrocarbon oils of include isoparaffinic oils (or isoparaffins), i.e., branched acyclic hydrocarbons, or cycloparaffinic oils (or cycloparaffins, also called naphthenic oils).

Synthetic isoparaffin oils may be produced by isomerization of predominantly linear hydrocarbons to produce branched hydrocarbons. Linear hydrocarbons may be naturally sourced, synthetically prepared, or derived from Fischer-Tropsch reactions or similar processes. Isoparaffins may be derived from hydro-isomerized wax and typically may be hydro-isomerised Fischer-Tropsch hydrocarbons or waxes. In one embodiment oils may be prepared by a Fischer-Tropsch gas-to-liquid synthetic procedure as well as other gas-to-liquid oils.

Suitable isoparaffins may also be obtained from natural, renewable, sources. Natural (or bio-derived) oils refer to materials derived from a renewable biological resource, organism, or entity, distinct from materials derived from petroleum or equivalent raw materials. Natural sources of hydrocarbon oil include fatty acid triglycerides, hydrolyzed or partially hydrolyzed triglycerides, or transesterified triglyceride esters, such as fatty acid methyl ester (or FAME). Suitable triglycerides include, but are not limited to, palm oil, soybean oil, sunflower oil, rapeseed oil, olive oil, linseed oil, and related materials. Other sources of triglycerides include, but are not limited to algae, animal tallow, and zooplankton. Linear and branched hydrocarbons may be rendered or extracted from vegetable oils and hydro-refined and/or hydro-isomerized in a manner similar to synthetic oils to produce isoparaffins.

Another class of isoparaffinic oils includes polyalphaolefins (PAO). Polyolefins are well known in the art. In one embodiment, the polyolefin may be derivable (or derived) from olefins with 2 to 28 carbon atoms. By derivable or derived it is meant the polyolefin is polymerized from the starting polymerizable olefin monomers having the noted number of carbon atoms or mixtures thereof. In embodiments, the polyolefin may be derivable (or derived) from olefins with 3 to 24 carbon atoms. In some embodiments, the polyolefin may be derivable (or derived) from olefins with 4 to 24 carbon atoms. In further embodiments, the polyolefin may be derivable (or derived) from olefins with 5 to 20 carbon atoms. In still further embodiments, the polyolefin may be derivable (or derived) from olefins with 6 to 18 carbon atoms. In still further embodiments, the polyolefin may be derivable (or derived) from olefins with 8 to 14 carbon atoms. In alternate embodiments, the polyolefin may be derivable (or derived) from olefins with 8 to 12 carbon atoms.

Often the polymerizable olefin monomers comprise one or more of propylene, isobutene, 1-butene, isoprene, 1,3-butadiene, or mixtures thereof. An example of a useful polyolefin is polyisobutylene.

Polyolefins also include poly-α-olefins derivable (or derived) from α-olefins. The α-olefins may be linear or branched or mixtures thereof. Examples include mono-olefins such as propylene, 1-butene, isobutene, 1-pentene, 1-hexene, 1-heptene, 1-octene, 1-nonene, 1-decene, etc. Other examples of α-olefins include 1-decene, 1-undecene, 1-dodecene, 1-tridecene, 1-tetradecene, 1-pentadecene, 1-hexadecene, 1-heptadecene 1-octadecene, and mixtures thereof. An example of a useful α-olefin is 1-dodecene. An example of a useful poly-α-olefin is poly-decene.

The polyolefin may also be a copolymer of at least two different olefins, also known as an olefin copolymer (OCP). These copolymers are preferably copolymers of α-olefins having from 2 to about 28 carbon atoms, preferably copolymers of ethylene and at least one α-olefin having from 3 to about 28 carbon atoms, typically of the formula CH₂═CHR₁ wherein R₁ is a straight chain or branched chain alkyl radical comprising 1 to 26 carbon atoms. Preferably R₁ in the above formula can be an alkyl of from 1 to 8 carbon atoms, and more preferably can be an alkyl of from 1 to 2 carbon atoms. Preferably, the polymer of olefins is an ethylene-propylene copolymer.

Where the olefin copolymer includes ethylene, the ethylene content is preferably in the range of 20 to 80 percent by weight, and more preferably 30 to 70 percent by weight. When propylene and/or 1-butene are employed as comonomer(s) with ethylene, the ethylene content of such copolymers is most preferably 45 to 65 percent, although higher or lower ethylene contents may be present.

The hydrocarbon (e.g., isoparaffinic) oils may be substantially free of ethylene and polymers thereof. The composition may be completely free of ethylene and polymers thereof. By substantially free, it is meant that the composition contains less than 50 ppm, or less than 30 ppm, or even less than 10 ppm or 5 ppm, or even less than 1 ppm of the given material.

The hydrocarbon (e.g., isoparaffinic) oils may be substantially free of propylene and polymers thereof. The hydrocarbon (e.g., isoparaffinic) oils may be completely free of propylene and polymers thereof. The polyolefin polymers prepared from the aforementioned olefin monomers can have a number average molecular weight of from 140 to 5000. The polyolefin polymers prepared from the aforementioned olefin monomers can also have a number average molecular weight of from 200 to 4750. The polyolefin polymers prepared from the aforementioned olefin monomers can also have a number average molecular weight of from 250 to 4500. The polyolefin polymers prepared from the aforementioned olefin monomers can also have a number average molecular weight of from 500 to 4500. The polyolefin polymers prepared from the aforementioned olefin monomers can also have a number average molecular weight of from 750 to 4000 as measured by gel permeation chromatography with polystyrene standard.

The isoparaffin oil can be a saturated hydrocarbon compound containing 8 carbon atoms up to a maximum of 50 carbon atoms and having at least one hydrocarbyl branch containing at least one carbon atom. In one embodiment, the saturated hydrocarbon compound can have at least 10 or at least 12 carbon atoms. In one embodiment, the saturated hydrocarbon compound can contain 14 to 34 carbon atoms with the proviso that the longest continuous chain of carbon atoms is no more than 24 carbons in length.

In embodiments, the isoparaffin oil will have a longest continuous chain of carbon atoms of no more than 24 carbons in length.

In embodiments, the saturated hydrocarbon compound can be a branched acyclic compound with a molecular weight of 140 g/mol to 550 g/mol as measured by size exclusion chromatography (SEC also called gel permeation chromatography or GPC), liquid chromatography, gas chromatography, mass spectrometry, NMR, or combinations thereof, or from 160 g/mol to 480 g/mol.

Mineral oils often contain cyclic structures, i.e., aromatics or cycloparaffins also called naphthenes. In one embodiment, the isoparaffin comprises a saturated hydrocarbon compound free of or substantially free of cyclic structures. By substantially free, it is meant there is less than 1 mol % of cyclic structures in the mineral oil, or less than 0.75 mol %, or less than 0.5 mol %, or even less than 0.25 mol %. In some embodiments, the mineral oil is completely free of cyclic structures.

In embodiments, the hydrocarbon oil can be a cycloparaffinic oil (cycloparaffins). Cycloparaffins may be obtained from mineral oil. Cycloparaffins contain at least one saturated hydrocarbyl 5- or 6-membered ring. Cycloparaffinic oils may contain at least 29 weight percent polycycloparaffins, i.e., 2 or more edge-sharing rings.

The hydrocarbon (e.g., isoparaffinic) oil is the base compound of the heat transfer fluid. As such, the hydrocarbon (e.g., isoparaffinic) oil makes up the balance of the composition after adding all oxygenate and other additives. The hydrocarbon oil may be present in an amount of at least 60 weight %, at least 70 weight %, at least 80 weight %, at least 90 weight %, or at least 95 weight % of the composition. That is to say, the hydrocarbon oil may be present in an amount of from 60 to 99 wt. %, or even from 70 to 98.5 wt. %, or from 80 to 98 wt. %, or from 90 to 97 or 97.5 wt. %. In some embodiments, the hydrocarbon oil may be present in an amount of from 80 to 99 wt. %, or even from 81 to 98.5 wt. %, or from 82 to 98 wt. %, or from 83 to 97 wt. %, or 84 to 97.5 wt. %.

### Oxygenate

The composition can also include an oxygenate substance that can act synergistically with the hydrocarbon (e.g., isoparaffinic) oils to effect improved heat transfer, reduced kinematic viscosity, reduced low temperature viscosity, or increased flash point.

As used herein, oxygenate refers to organic (i.e., carbon containing, also known as hydrocarbon) compounds containing oxygen as one of their components. Oxygenates, as used herein, include hydrocarbons having at least 1 aprotic or protic oxygen for every 2 carbon atoms, or for every 3 carbon atoms, or for every 4 carbon atoms, or for every 5 carbon atoms, or for every 6 carbon atoms. Oxygenates also include hydrocarbons having at least 1 aprotic or protic oxygen for every 7 carbon atoms, or 1 aprotic or protic oxygen for every 8 carbon atoms, or at least 1 aprotic or protic oxygen for every 12 carbon atoms. Oxygenates also include hydrocarbons having at least 1 aprotic or protic oxygen for every 16 carbon atoms, or 1 aprotic or protic oxygen for every 20 carbon atoms.

Oxygenates can include, for example, alcohols, ester oils and ether oils. The oxygenate may be included in the heat transfer fluid at from about 1 to about 45 wt. %, or in some instances, from about 1.5 to about 40 wt. %, or about 2 to about 35 wt. %. The oxygenate may also be included in the heat transfer fluid at from about 2.5 to about 30 wt. % or about 3 to about 25 wt. %. In some embodiments, the oxygenate may be included in the heat transfer fluid at from 1 to about 20 wt. %, or in some instances from about 1.5 to about 19 wt. %, or about 2 to about 18 wt. %. The oxygenate may also be included in the heat transfer fluid at from about 2.5 to about 17 wt. %, or 3 to about 16 wt. %.

Alcohols suitable for use in the heat transfer fluid include monohydric alcohols, for example, ethanol, methanol, propylene alcohol derivatives such as n-butanol and tert-butanol, as well as isopropyl alcohol; higher branched alcohols include isomers of pentanol, hexanol, heptanol, octanol, decanol, dodecanol, tetradecanol, hexadecanol and combinations thereof. Examples of branched alcohols include 2-ethylhexanol, iso-octanol, iso-decanol, and isododecanol. Alcohols as used herein also encompass polyols, such as, for example propylene glycol, ethylene glycol, 1,4-butanediol, pentaerythritol, trimethylolpropane.

Ethers suitable for use as oxygenates in the heat transfer fluid include those made from petrochemical feedstocks as well as renewable feedstocks. Examples include methyl tertiary butyl ether (MTBE), tertiary amyl methyl ether (TAME), ethyl tertiary butyl ether (ETBE), and tertiary amyl ethyl ether (TAEE). Other ether examples include tert-hexyl methyl ether (THEME), dioctyl ether, and diisopropyl ether. Polyethers are also considered herein in the term “ethers,” including, for example, diethylene glycol dibutyl ether. Low molecular weight oligomers of polyalkylene glycols (i.e., polyalkylene oxides) may also be suitable, including polyethylene glycol (PEG), polypropylene glycol (PPG), and mixed polymers thereof. Polyethers include alkylene oxide polymers and oligomers containing 1 to 20 repeat units, or 2 to 10 repeat units, or 2 to 5 repeat units of ethylene oxide, propylene oxide, n-butylene oxide, or mixtures thereof. Suitable polyether compounds include: 5,8,11,14-tetraoxaicosane; 1-(2-(2-butoxypropoxy) propoxy) propan-2-yl acetate; 2-(2-(2-(hexyloxy) ethoxy) ethoxy)ethyl oleate; 1-((1-((1-butoxypropan-2-yl)oxy) propan-2-yl)oxy) butane; 7,10,13,16,19-pentaoxaheptacosane; 2-(2-(2-(hexyloxy) ethoxy) ethoxy)ethyl 3,5,5-trimethylhexanoate; and combinations thereof.

The oxygenate may also be a polyalkylene glycol esters by reacting polyalkylene glycols with fatty acids, such as, for example, caprylic acid, myristic acid, palmitic acid, stearic acid, and the like.

In some instances, the oxygenate may be an alcohol or an ether and may be included in the heat transfer fluid at from about 1 to about 45 wt. %, or in some instances, from about 1.5 to about 40 wt. %, or about 2 to about 35 wt. %. Alcohol or ether oxygenates may also be included in the heat transfer fluid at from about 2.5 to about 30 wt. % or about 3 to about 25 wt. %.

Ester oils suitable for use as oxygenates in the heat transfer fluid include, for example, esters of monocarboxylic acids with monohydric alcohols; di-esters of diols with monocarboxylic acids and di-esters of dicarboxylic acids with monohydric alcohols; polyol esters of monocarboxylic acids and polyesters of monohydric alcohols with polycarboxylic acids; and mixtures thereof. Esters may be broadly grouped into two categories: synthetic and natural.

Synthetic esters suitable for use as oxygenates in the heat transfer fluids may comprise esters of monocarboxylic acid (such as acetic acid, propionic acid, neopentanoic acid, 2-ethylhexanoic acid) and dicarboxylic acids (e.g., phthalic acid, succinic acid, alkyl succinic acids and alkenyl succinic acids, maleic acid, azelaic acid, suberic acid, sebacic acid, fumaric acid, adipic acid, linoleic acid dimer, malonic acid, alkyl malonic acids, and alkenyl malonic acids) with any of variety of monohydric alcohols (e.g., butyl alcohol, pentyl alcohol, neopentyl alcohol, hexyl alcohol, octyl alcohol, iso-octyl alcohol, nonyl alcohol, decyl alcohol, isodecyl alcohol, dodecyl alcohol, tetradecyl alcohol, hexadecyl alcohol, 2-ethylhexyl alcohol, ethylene glycol, diethylene glycol monoether, and propylene glycol). Specific examples of these esters include dibutyl adipate, di(2-ethylhexyl) sebacate, di-n-hexyl fumarate, dioctyl sebacate, diisooctyl azelate, diisodecyl azelate, dioctyl phthalate, didecyl phthalate, dieicosyl sebacate, the 2-ethylhexyl diester of linoleic acid dimer, and the complex ester formed by reacting one mole of sebacic acid with two moles of tetraethylene glycol and two moles of 2-ethylhexanoic acid. Other synthetic esters include those made from C₅ to C₁₂ monocarboxylic acids and polyols and polyol ethers such as neopentyl glycol, trimethylolpropane, pentaerythritol, dipentaerythritol, and tripentaerythritol. Esters can also be monoesters of mono-carboxylic acids and monohydric alcohols.

Suitable esters also include esters of hydroxy-substituted carboxylic acids, such as tartaric acid, malic acid, glycolic acid, and hydroxy fatty acids (e.g., 12-hydroxystearic acid) in combination with monohydric alcohols as above.

Natural (or bio-derived) esters refer to materials derived from a renewable biological resource, organism, or entity, distinct from materials derived from petroleum or equivalent raw materials. Natural esters suitable in the heat transfer fluids include fatty acid triglycerides, hydrolyzed or partially hydrolyzed triglycerides, or transesterified triglyceride esters, such as fatty acid methyl ester (or FAME). Suitable triglycerides include, but are not limited to, palm oil, soybean oil, sunflower oil, rapeseed oil, olive oil, linseed oil, and related materials. Other sources of triglycerides include, but are not limited to, algae, animal tallow, and zooplankton.

In some instances, the oxygenate may be an ester, which may be included in the heat transfer fluid at from about 1 to about 20 wt. %, or in some instances from about 1.5 to about 19 wt. %, or about 2 to about 18 wt. %. Ester oxygenates may also be included in the heat transfer fluid at from about 2.5 to about 17 wt. %, or 3 to about 16 wt. %.

### Heat Transfer Additives

The heat transfer fluid can also include heat transfer additives. One class of heat transfer additives is phase change materials. Phase change materials are known and are materials that absorb or release heat while changing phase, e.g., solid to liquid and vice versa. There are many types of phase change materials, and they can include, for example, materials that change phase from solid to liquid over a range of different temperatures. For example, phase change materials may include materials that change from solid to liquid between 2° and 200° C., that is, materials having a melting temperature between, for example, 20 and 80° C., or 100 and 200° C. The phase change materials can also include materials having a melting temperature between, for example, 30 and 200° C., or 40 and 200° C., or 20 and 150° C., or 20 and 100° C. The phase change materials can also include materials having a melting temperature between, for example, 30 and 80° C., or 40 and 80° C., or 20 and 40° C., or 30 and 60° C., or 40 and 50° C. The phase change materials can also include materials having a melting temperature between, for example, 100 and 200° C., or 120 and 200° C., or 100 and 175° C., or 100 and 150° C. Those of ordinary skill in the art can readily determine the melting temperature of a substance employing Modulated Differential Scanning calorimetry (“DSC”). ASTM E793 is a Standard Test Method for Enthalpies of Fusion and Crystallization by Differential Scanning calorimetry and may be used for determining melting temperatures. The particular method employed herein was to place a small amount of sample (7-10 mg) in a pan in a calorimeter along with a reference pan. The calorimeter performs a temperature ramp, for example from −80° C. to ˜80° C., at a specified heating rate, for example 2 or 4° C./min. The temperature of the sample pan is compared to the reference pan as the heat (energy) is applied until a phase change is observed. At this temperature, the measured temperatures of the sample pan will remain constant until the material has entirely changed phase whereas the reference pan will continue to rise in temperature. The temperature that this happens at is the melting temperature, or more accurately, the phase change temperature. The specific phase change material for a particular application will be chosen depending on the thermal profile of the application and the desired heat absorption range. Combinations of phase change materials may be employed to provide a custom thermal gradient. Phase change materials include materials that (a) may change phase and remain suspended or miscible with the oil, (b) include blocks or sidechains that change phase while other blocks or backbone remain miscible with the oil, or (c) are encapsulated so that the encapsulant remains suspended while the phase change material absorbs or releases heat while changing phase.

Phase change materials can include, for example, paraffinic hydrocarbons, carboxylic acids, alcohols, and certain polymers.

Examples of paraffinic hydrocarbon phase change materials include those having between about 17 and 30 carbon atoms, such as n-Heneicosane, n-docosane, n-Tricosane, and n-Tetracosane. A table of example paraffinic hydrocarbons is presented below.

| | | Melting |
|---|---|---|
| Compound | # of Carbon | Point |
| Name | Atoms | (° C.) |
| n-Octacosane | 28 | 61.4 |
| n-Heptacosane | 27 | 59 |
| n-Hexacosane | 26 | 56.4 |
| n-Pentacosane | 25 | 53.7 |
| n-Tetracosane | 24 | 50.9 |
| n-Tricosane | 23 | 47.6 |
| n-Docosane | 22 | 44.4 |
| n-Heneicosane | 21 | 40.5 |
| n-Eicosane | 20 | 36.8 |
| n-Nonadecane | 19 | 32.1 |
| n-Octadecane | 18 | 28.2 |
| n-Heptadecane | 17 | 22 |

In some embodiments the paraffinic hydrocarbon can be a wax, meaning less than one branch for every 10 carbons, or even less than one branch for every 20 carbons.

Examples of carboxylic acids phase change materials include Lauric acid, Myristic acid, tridecylic acid, methyl eicosanate, and methyl behenate.

Examples of alcohol phase change materials can include both phenol type alcohols and fatty alcohols. Examples of phenol compounds can include phenol per se, as well as substituted phenols such as, for example, 4-Ethylphenol. Fatty alcohols can include, for example, 1-Pentadecanol, cetyl alcohol, and 1-Tetradecanol.

Polymers may also be employed as phase change materials. For example, some polyethylene glycols (“PEG”) have suitable melting temperatures to act as phase change materials, such as, for example, PEG 1000, PEG 2000, and PEG 4000 as well as certain thermoplastics. Suitable polymers include poly(alpha) olefins, alpha olefin-maleic anhydride (AOMA) copolymers, maleic anhydride-styrene copolymers (MSC), poly(meth)acrylates (PMA), styrene-diene block copolymers (such as styrene-butadiene and/or styrene-isoprene block co-polymers), polyurethanes, and polyesters, especially polyesters of hydroxy-substituted fatty acids.

Acrylate and methacrylate (referred to collectively herein as (meth)acrylate) polymers and copolymers with one, two or more blocks, wherein at least one block undergoes a phase change, may also be employed as phase change materials.

Such poly(meth)acrylate phase change materials can be prepared from a monomer mixture comprising (meth)acrylate monomers having alkyl groups of varying length. The (meth)acrylate monomers may contain alkyl groups that are straight chain or branched chain groups or aromatic groups. The alkyl groups may contain 1 to 24 carbon atoms, for example 1 to 20 carbon atoms. In some embodiments, the poly(meth)acrylate phase change materials can be formed from monomers derived from saturated alcohols. In embodiment the poly(meth)acrylate phase change materials can be prepared from monomers derived from long-chain alcohol-derived groups

Such poly(meth)acrylate polymer phase change materials can also include a dispersant monomer. Dispersant monomers include those monomers which may copolymerize with (meth)acrylate monomers and contain one or more heteroatoms in addition to the carbonyl group of the (meth)acrylate. The dispersant monomer may contain a nitrogen-containing group, an oxygen-containing group, or mixtures thereof.

Such poly(meth)acrylates may be block copolymer or tapered block copolymer. In some embodiments, the poly(meth)acrylate copolymers can include block or tapered block poly(meth)acrylate polymers (P) which have a first block (B1) that undergoes a phase change, and which optionally is substantially insoluble or insoluble in the hydrocarbon oil of the lubricating composition and a second block (B2) which is substantially soluble or soluble in the hydrocarbon oil of the lubricating composition. The first block may comprise one or more monomers that form polymers which undergo a phase change in the desired temperature regimes of the invention, and which are optionally substantially insoluble in the base oil. These poly(meth)acrylate polymers are further taught in WO2019/005738 published Jan. 3, 2019, to Vincent et al., paragraphs to of which are incorporated herein by reference.

In some instances, the phase change material may include side chains that change phases while the backbone of the material remains suspended or solubilized in the oil.

Some of the phase change materials may require encapsulation within the heat transfer fluid. The term “encapsulation” and its alternate forms means that the phase change material is coated in some way with a polymer shell. In some instances, an encapsulating material may be used to encapsulate the phase change material in a surfactant type manner. In other instances, the phase change material may include a hydrophobic tail sufficient to surround, or “encapsulate,” itself. For example, (meth)acrylate) polymers and copolymers may contain two or more blocks, wherein at least one block undergoes the phase change, and at least one block acts as an “encapsulant” to the phase change block. Encapsulated phase change materials are known in the art and are just what they sound like, a phase change material encapsulated by an encapsulant. Where a separate encapsulant material is needed for a phase change material, encapsulating materials can include any known encapsulant for phase change materials. Methods of encapsulation are well-known in the art and any method now known or later developed may be employed to provide an encapsulant for the phase change material. Methods can include, for example, chemical processes, such as interfacial polymerization or in-situ polymerization, physio-chemical processes, such as coacervation and phase separation, sol-gel encapsulation or solvent evaporation, and mechanical processes, such as spray drying and congealing, or one of several coating processes. Encapsulants can include, for example, surfactants, polymer shell, and inorganic encapsulants like metal oxide.

In one embodiment, encapsulation of phase change material with surfactants can be generated through high shear emulsification with the assistance of surfactant molecules. Surfactants are readily known to those of ordinary skill in the art and one of ordinary skill would readily be able to determine the best surfactant to prepare an encapsulated phase change material.

Encapsulation of phase change material with polymerization can be formed in-situ through interfacial polymerization around emulsion droplets of the phase change material. Typical monofunctional polymer shells for encapsulation can be polystyrene, polymethyl methacrylate, melamine formaldehyde or polyurethane.

Encapsulation of phase change material with inorganic materials can be achieved, for example with a metal oxide. In this method, a metal oxide shell can be formed in-situ with hydrolysis around the emulsion droplets of the phase change material. Metal oxide shells can be, for example, silica, alumina, or titania.

Encapsulation of the phase change material can help to form stable dispersions of the phase change material in the heat transfer fluid without rapidly increasing its viscosity. The high surface area-to-volume of the encapsulated phase change material can increase the kinetics of phase change reaction. Ideally, the diameter of the encapsulated phase change material would be smaller than 1000 nm, or small than 750 nm, or small than 500 nm or in some instances smaller than 400 nm.

The phase change materials can be included in the heat transfer fluid at concentrations suitable to remove the desired amount of heat (Q) from the particular system in view. One of ordinary skill knowing how much heat being desired to remove from a system would readily be able to determine such concentrations by determining, or looking up, the specific latent heat (L) of the phase change material or materials, and adding a mass (m) of such phase change material or materials sufficient to absorb that heat, according to the equation m=Q/L. In general, the phase change materials can be included in the heat transfer fluids as a single-phase change material or a combination of phase change materials at concentrations anywhere from 1, or even less to 50 wt. %, or even more, of the heat transfer fluid. The phase change materials can also be included from 10 to about 48 wt. % or even from about 20 to 45 wt. % or even from about 25 to 42 wt. % or 30 to 40 wt. %.

Heat transfer additives for the heat transfer fluid can also include halogenated hydrocarbons, which as used herein include halogenated ethers as well as halogenated amines. Halogenated hydrocarbons are hydrocarbons in which a majority of the hydrogen protons have been replaced synthetically by a halogen. The halogen can be any of the halogen compounds, but often is chlorine or fluorine, and most often is fluorine. Fluorinated hydrocarbons, or fluorocarbons, are known in the art and can include, for example, perfluoroalkene, perfluoroalkanes, perfluoroethers, and perfluoroamines.

Any known halogenated hydrocarbon soluble in the heat transfer fluid may be employed as a heat additive. In embodiments, the halogenated hydrocarbon may be selected by choosing the boiling point of the halogenated hydrocarbon to be up to 5% lower than the flash point of the hydrocarbon oil. The boiling point of the halogenated hydrocarbon may be between from 5% lower to equal to the flash point of the hydrocarbon oil. In some embodiments, the boiling point of the halogenated hydrocarbon may be between from 2.5% lower to equal to the flash point of the hydrocarbon oil, or even from 1% or 0.5% lower to equal to the flash point of the hydrocarbon oil.

The heat transfer fluid can include halogenated hydrocarbon in broad amounts from 0.1 to 75 wt. % or more. Often the halogenated hydrocarbon is included at lesser concentrations of from about 0.25 to 50 wt. %, or even 0.5 to 25 wt. %, or 1 to 10 wt. % or even 1 to 5 wt. %. From a cost/benefit perspective, it has been found halogenated hydrocarbons can provide benefit in the heat transfer fluids disclosed herein at concentrations of from 0.1 to 5 wt. %, or even from 0.25 to 4 wt. %, or from 0.5 to 3 wt. % or even 0.75 to 2 wt. %.

Another class of heat transfer additive includes, for example, metal and non-metal particles. Particles of the invention are generally dispersed solids, often dispersed in the presence of one or more stabilizers or surfactants. The particles of the invention are often sub-micron in size and are also referred to as nanoparticles.

For metal nanoparticles, the metal of the metal nanoparticles can include an alkaline earth metal, for example, magnesium, calcium, strontium, and barium.

The metal of the metal nanoparticles can include a transition metal, for example, scandium, yttrium, titanium, zirconium, hafnium, vanadium, niobium, tantalum, chromium, molybdenum, tungsten, manganese, technetium, rhenium, iron, ruthenium, osmium, cobalt, rhodium, iridium, nickel, palladium, platinum, copper, silver, gold, zinc, and cadmium.

The metal of the metal nanoparticles can include a lanthanide series or actinide series metal, for example, lanthanum, cerium, praseodymium, neodymium, promethium, samarium, europium, gadolinium, terbium, dysprosium, holmium, erbium, thulium, ytterbium, lutetium, thorium, protactinium, and uranium).

The metal of the metal nanoparticles can include a post-transition metal, for example, aluminum, gallium, indium, thallium, tin, lead, bismuth, and polonium.

The metal of the metal nanoparticles can include a metalloid, for example, boron, silicon, germanium, and antimony.

In certain embodiments, the metal can include aluminum. In embodiments, the metal can include iron. The metal can also include ruthenium. The metal can include cobalt. The metal can include rhodium. The metal can include nickel. The metal can include palladium. The metal can include platinum. The metal can include silver. The metal can include gold. The metal can include cerium. The metal can include samarium. The metal can include tungsten.

The metal nanoparticles can be present in their pure form, or, as an oxide, carbide, nitride, or mixture of any of these materials or combination of materials.

For example, the metal nanoparticles can be iron oxide (e.g., Fe₂O₃, Fe₃O₄), cobalt oxide (e.g., CoO), zinc oxide (e.g., ZnO), cerium oxide (e.g., CeO₂), and titanium oxide (e.g., TiO₂). Boron Oxide (e.g., B₂O₃) is another metal nanoparticle that may be employed. Aluminum Oxide (e.g., Al₂O₃) is another metal nanoparticle that may be employed. Magnesium oxide (e.g., MgO) is another metal nanoparticle that may be employed. Tungsten oxide (e.g., W₂O₃, WO₂, WO₃, W₂O₅) is another metal nanoparticle that may be employed.

Examples of metal carbide metal nanoparticles can include iron carbide (e.g., Fe₃CH₄), cobalt carbide (e.g., CoC, Co₂C, Co₃C), zinc carbide (e.g., ZnC), cerium carbide (e.g., CeC₂), and titanium carbide (e.g., TiC). Boron carbide (e.g., B₄C) is another metal nanoparticle that may be employed. Aluminum carbide (e.g., Al₄C₃) is another metal nanoparticle that may be employed. Tungsten carbide (e.g., WC) is another metal nanoparticle that may be employed.

Examples of metal nitride metal nanoparticles can include iron nitride (e.g., Fe₂N, Fe₃N₄, Fe₄N, Fe₇N₃, Fe₁₆N₂), cobalt nitride (e.g., Co₂N, Co₃N, Co₄N), zinc nitride (e.g., Zn₃N₂), cerium nitride (e.g., CeN), and titanium nitride (e.g., TiN). Boron nitride (e.g., BN) is another metal nanoparticle that may be employed. Aluminum nitride (e.g., AlN) is another metal nanoparticle that may be employed. Tungsten nitride (e.g., WN, W₂N, WN₂) is another metal nanoparticle that may be employed.

The nanoparticles can also include non-metal nanoparticles. Such non-metal nanoparticles can be present in the form of oxides, carbon, carbides, nitrides, or mixture of any of these materials or combination of materials. For example, the non-metal nanoparticles can be graphene oxide or diamond.

The nanoparticle can have a D50 particle size of less than 1000 nm. In some embodiments, the nanoparticles can have a D50 particle size of less than 700 nm. The nanoparticle can have a D50 particle size of less than 500 nm. The nanoparticle can have a D50 particle size of less than 250 nm. The nanoparticle can have a D50 particle size of less than 100 nm. The nanoparticle can have a D50 particle size of less than 75 nm. The nanoparticle can have a D50 particle size of less than 50 nm. The nanoparticle can have a D50 particle size of 0.01 nm to 1000 nm. The nanoparticle can also have a D50 particle size of 0.1 nm to 100 nm. The nanoparticle can have a D50 particle size of 1 nm to 75 nm. The nanoparticle can have a D50 particle size of 10 nm to 50 nm. D50 particle sizes can be measured by Dynamic Light Scattering according to ASTM E2490-09 (2015).

The nanoparticle can have an average aspect ratio of from 1 to 5000. As used herein, the “average aspect ratio” refers to the average ratio of the length of the particles in a nanoparticle mixture to the width of the particles in the mixture. The term “average” is intended to mean that any and all aspect ratios may be present, but that the average aspect ratio over the aggregate is in the disclosed range. The measurement method for determining the length and width for the average aspect ratio are not critical so long as the same measurement method is used for both the measurements. The nanoparticle can also have an average aspect ratio of from 1 to 2500. The nanoparticle can also have an average aspect ratio of from 1 to 1000. The nanoparticle can also have an average aspect ratio of from 1 to 500. The nanoparticle can also have an average aspect ratio of from 1 to 250. The nanoparticle can also have an average aspect ratio of from 1 to 100. The nanoparticle can also have an average aspect ratio of from 1 to 50. The nanoparticle can also have an average aspect ratio of from 1 to 25. The nanoparticle can also have an average aspect ratio of from 1 to 10. The nanoparticle can also have an average aspect ratio of from 10 to 5000. The nanoparticle can also have an average aspect ratio of from 25 to 5000. The nanoparticle can also have an average aspect ratio of from 50 to 5000. The nanoparticle can also have an average aspect ratio of from 100 to 5000. The nanoparticle can also have an average aspect ratio of from 250 to 5000. The nanoparticle can also have an average aspect ratio of from 500 to 5000. The nanoparticle can also have an average aspect ratio of from 1000 to 5000. The nanoparticle can also have an average aspect ratio of from 2500 to 5000.

In general, the nanoparticle will be selected to have a thermal conductivity greater than the thermal conductivity of the heat transfer fluid. In some embodiments, the heat transfer fluid can include a particle having a minimum thermal conductivity of greater than 5 W/m-K. In some embodiments, the heat transfer fluid can include a nanoparticle having a thermal conductivity of 10 W/m-K or greater. In some embodiments, the heat transfer fluid can include a nanoparticle having a thermal conductivity of 30 W/m-K or greater. In some embodiments, the heat transfer fluid can include a nanoparticle having a thermal conductivity of 250 W/m-K or greater. In some embodiments, the heat transfer fluid can include a nanoparticle having a thermal conductivity of 500 W/m-K or greater. In some embodiments, the heat transfer fluid can include a nanoparticle having a thermal conductivity of 1000 W/m-K or greater. As used herein, thermal conductivity can be measured by ASTM D7896-19.

The heat transfer fluid can include the at least one nanoparticle at a concentration of from 0.5 to 30 wt % based on the weight of the heat transfer fluid. In some embodiments, the heat transfer fluid can include the at least one nanoparticle at a concentration of from 0.75 to 25 wt %. In some embodiments, the heat transfer fluid can include the at least one nanoparticle at a concentration of from 1 to 20 wt %. In embodiments, the heat transfer fluid can include the at least one nanoparticle at a concentration of from 1.25 to 15 wt %. In some embodiments, the heat transfer fluid can include the at least one nanoparticle at a concentration of from 1.5 to 10 wt %.

However, when dosing the nanoparticle, care should be taken not to exceed the dielectric constant constraints for the heat transfer fluid. Generally, this will not be an issue except where more electrically conductive nanoparticles are employed, such as nanoparticles in the form of pure metals, and generally at high levels, such as 10 wt % or more. Where there is concern, the heat transfer fluid can be formulated, and the dielectric constant of the dispersion tested.

The nanoparticles are often dosed with a surfactant suitable to associate with nanoparticles and keep the nanoparticles dispersed in the heat transfer fluid, as would be readily apparent to those of skill in the art. Surfactants can include any surfactant or dispersant now known or still to be created.

In one embodiment, the heat transfer fluid can include a hydrocarbon oil, one or more polyether oxygenates, and one or more metal or non-metal particles.

### Performance Additives

The heat transfer fluid can also include a performance additive package that balances the volume resistivity and conductivity of the fluid. The performance additive package can include metal containing detergent and dispersant.

The heat transfer fluid may also include a metal-containing detergent.

The metal-containing detergent may be an overbased detergent, a non-overbased detergent, or mixtures thereof. Typically, the detergent is overbased.

The metal-containing detergent may be a non-overbased detergent (may also be referred to as a neutral detergent). The TBN of a non-overbased metal-containing detergent may be 20 to less than 200, or 30 to 100, or 35 to 50 mg KOH/g. The TBN of a non-overbased metal-containing detergent may also be 20 to 175, or 30 to 100 mg KOH/g. When a non-overbased metal-containing detergent is prepared from a strong acid such as a hydrocarbyl-substituted sulfonic acid, the TBN may be lower (for example 0 to 50 mg KOH/g, or 10 to 20 mg KOH/g).

As used herein the TBN values quoted and associated range of TBN is on “an as is basis,” i.e., containing conventional amounts of diluent oil. Conventional amounts of diluent oil typically range from 30 wt % to 60 wt % (often 40 wt % to 55 wt %) of the detergent component.

The metal-containing detergent may be an overbased detergent, having, for example, a TBN of greater than 200 mg KOH/g (typically 250 to 600, or 300 to 500 mg KOH/g).

The overbased metal-containing detergent may be formed by the reaction of a basic metal compound and an acidic detergent substrate. The acidic detergent substrate may include an alkyl aromatic sulfonic acid (such as, alkyl naphthalene sulfonic acid, alkyl toluene sulfonic acid or alkyl benzene sulfonic acid), an alkyl salicylic acid, or mixtures thereof.

The basic metal compound is used to supply basicity to the detergent. The basic metal compound is a compound of a hydroxide or oxide of the metal. The metal of the metal-containing detergent may be an alkaline or alkaline earth metal, such as, for example, zinc, sodium, calcium, barium, or magnesium. Typically, the metal of the metal-containing detergent may be sodium, calcium, or magnesium.

In one embodiment the metal-containing detergent may be a sulfonate, or mixtures thereof. The sulfonate may be prepared from a mono- or di-hydrocarbyl-substituted benzene (or naphthalene, indenyl, indanyl, or bicyclopentadienyl) sulfonic acid, wherein the hydrocarbyl group may contain 6 to 40, or 8 to 35 or 9 to 30 carbon atoms.

The hydrocarbyl group may be derived from polypropylene or a linear or branched alkyl group containing at least 10 carbon atoms. Examples of a suitable alkyl group include branched and/or linear decyl, undecyl, dodecyl, tridecyl, tetradecyl, pentadecyl, hexadecyl, heptadecyl, octadecyl, octadecenyl, nonodecyl, eicosyl, un-eicosyl, do-eicosyl, tri-eicosyl, tetra-eicosyl, penta-eicosyl, hexa-eicosyl or mixtures thereof.

In one embodiment the hydrocarbyl-substituted sulfonic acid may include polypropene benzenesulfonic acid and/or C₁₆-C₂₄ alkyl benzenesulfonic acid, or mixtures thereof.

In one embodiment a metal sulfonate detergent may be a predominantly linear alkylbenzene sulfonate detergent having a metal ratio of at least 8. In some embodiments the linear alkyl group may be attached to the benzene ring anywhere along the linear chain of the alkyl group, but often in the 2, 3 or 4 position of the linear chain, and in some instances predominantly in the 2 position.

When neutral or slightly basic, a metal sulfonate detergent may have TBN of less than 100, or less than 75, typically 20 to 50 mg KOH/g, or 0 to 20 mg KOH/g.

When overbased, a metal sulfonate detergent may have a TBN greater than 200, or 300 to 550, or 350 to 450 mg KOH/g.

Phenate detergents are typically derived from p-hydrocarbyl phenols or, generally, alkylpheols. Alkylphenols of this type may be coupled with sulfur and overbased, coupled with aldehyde and overbased, or carboxylated to form salicylate detergents. Suitable alkylsalicylates include those alkylated with oligomers of propylene, oligomers of butene, especially tetramers and pentamers of n-butenes, as well as those alkylated with alpha-olefins, isomerized alpha-olefins, and polyolefins like polyisobutylene.

The metal containing detergent may be overbased. Overbased detergents are known in the art. Overbased materials, otherwise referred to as overbased or super-based salts, are generally single phase, homogeneous Newtonian systems characterized by a metal content in excess of that which would be present for neutralization according to the stoichiometry of the metal and the particular acidic organic compound reacted with the metal. The overbased materials are prepared by reacting an acidic material (typically an inorganic acid or lower carboxylic acid, preferably carbon dioxide) with a mixture comprising an acidic organic compound, a reaction medium comprising at least one inert, organic solvent (mineral oil, naphtha, toluene, xylene, etc.) for said acidic organic material, a stoichiometric excess of a metal base, and a promoter such as a calcium chloride, acetic acid, phenol or alcohol. The acidic organic material will normally have a sufficient number of carbon atoms to provide a degree of solubility in oil. The amount of excess metal is commonly expressed in terms of metal ratio. The term “metal ratio” is the ratio of the total equivalents of the metal to the equivalents of the acidic organic compound. A neutral metal salt has a metal ratio of one. A salt having 4.5 times as much metal as present in a normal salt will have metal excess of 3.5 equivalents, or a ratio of 4.5. The term “metal ratio is also explained in standard textbook entitled “Chemistry and Technology of Lubricants”, Second Edition, Edited by R. M. Mortier and S. T. Orszulik, Copyright 1997.

Overbased metal-containing detergent may be, for example, non-sulfur containing phenates, sulfur containing phenates, sulfonates, salixarates, salicylates, and mixtures thereof, or borated equivalents thereof. The overbased detergent may be borated with a borating agent such as boric acid.

The overbased metal-containing detergent may also include “hybrid” detergents formed with mixed surfactant systems including phenate and/or sulfonate components, e.g., phenate/salicylates, sulfonate/phenates, sulfonate/salicylates, sulfonates/phenates/salicylates. Where, for example, a hybrid sulfonate/phenate detergent may be employed, the hybrid detergent would be considered equivalent to amounts of distinct phenate and sulfonate detergents introducing like amounts of phenate and sulfonate soaps, respectively.

Typically, an overbased metal-containing detergent may be a zinc, sodium, calcium or magnesium salt of a phenate, sulfur containing phenate, sulfonate, salixarate or salicylate. Overbased salixarates, phenates and salicylates typically have a total base number of 180 to 450 TBN. Overbased sulfonates typically have a total base number of 250 to 600, or 300 to 500. Overbased detergents are known in the art. In one embodiment the sulfonate detergent may be a predominantly linear alkylbenzene sulfonate detergent having a metal ratio of at least 8. The predominantly linear alkylbenzene sulfonate detergent may be particularly useful for assisting in improving fuel economy.

Typically, the overbased metal-containing detergent may be a calcium or magnesium overbased detergent, such as a calcium sulfonate or magnesium sulfonate detergent.

Detergent may be included in the heat transfer fluid at from 10 ppm to 5000 ppm, 25 ppm to 4000 ppm, 50 ppm to 3000 ppm, 100 ppm to 2000 ppm, 50 ppm to 500 ppm.

The dispersant (also called surfactant) may be a succinimide dispersant, a Mannich dispersant, a succinamide dispersant, a succinic acid ester, amide, or ester-amide, or mixtures thereof. In one embodiment the dispersant may be present as a single dispersant. In one embodiment the dispersant may be present as a mixture of two or three different dispersants, wherein at least one may be a succinimide dispersant. In embodiments, the heat transfer fluid can include both succinimide and polyolefin succinic acid ester dispersant.

The succinimide dispersant may be derived from an aliphatic amine, polyamine, hydroxy-substituted amines, or mixtures thereof. The aliphatic polyamine may be aliphatic polyamine such as an ethylenepolyamine, a propylenepolyamine, a butylenepolyamine, or mixtures thereof. In one embodiment the aliphatic polyamine may be ethylenepolyamine. In one embodiment the aliphatic polyamine may be selected from the group consisting of ethylenediamine, di ethylenetriamine, triethyl enetetramine, tetraethyl enepentamine, pentaethylenehexamine, polyamine still bottoms, and mixtures thereof.

The succinimide dispersant may be derived from an aromatic amine, aromatic polyamine, or mixtures thereof. The aromatic amine may have one or more aromatic moieties linked by a hydrocarbylene group and/or a heteroatom. In certain embodiments, the aromatic amine may be a nitro-substituted aromatic amine. Examples of nitro-substituted aromatic amines include 2-nitroaniline, 3-nitroaniline, and 4-nitroaniline (typically 3-nitroaniline). The succinimide dispersant may be derived from 4-aminodiphenylamine, or mixtures thereof.

In one embodiment the dispersant may be a succinic acid ester, amide, or ester-amide. For instance, a polyolefin succinic acid ester may be a polyisobutylene succinic acid ester of pentaerythritol, or mixtures thereof. A polyolefin succinic acid ester-amide may be a polyisobutylene succinic acid reacted with an alcohol (such as pentaerythritol) and an amine (such as a diamine, typically diethyleneamine).

In one embodiment the dispersant may be a hydrocarbyl succinic acid ester or ester-acid mixture. The hydrocarbyl group may be a branched or linear hydrocarbyl group of 8 to 60 carbon atoms. In one embodiment, the hydrocarbyl succinate ester may be a C10 to C22 hydrocarbyl succinate. Examples include decyl succinate, dodecylsuccinate, tetradecylsuccinate, hexadecylsuccinate, octadecdylsuccinate, and combinations thereof. The succinate ester may be derived from aliphatic alcohols, aliphatic polyols, amine-substituted aliphatic alcohols, and combinations thereof. Suitable alcohols include N,N-dimethylethanolamine, propane diol, trimethylolpropane, and pentaerythritol.

The dispersant may be an N-substituted long chain alkenyl succinimide. An example of an N-substituted long chain alkenyl succinimide is polyisobutylene succinimide. Typically, the polyisobutylene from which polyisobutylene succinic anhydride is derived has a number average molecular weight of 350 to 5000, or 550 to 3000 or 750 to 2500.

The dispersants may also be post-treated by conventional methods by a reaction with any of a variety of agents. Among these are boron compounds (such as boric acid), urea, thiourea, dimercaptothiadiazoles, carbon disulphide, aldehydes, ketones, carboxylic acids such as terephthalic acid, hydrocarbon-substituted succinic anhydrides, maleic anhydride, nitriles, epoxides, and phosphorus compounds. In one embodiment the post-treated dispersant is borated. In one embodiment the post-treated dispersant may be reacted with dimercaptothiadiazoles. In one embodiment the post-treated dispersant may be reacted with phosphoric or phosphorous acid.

Boron post-treated dispersants may be present in an amount to deliver 0 to 500 ppm boron to the composition, or 5 to 250 ppm boron, or 10 to 150 ppm boron, or 20 to 100 ppm boron to the composition.

Polyalkenyl dispersant-PIB dispersant-succinate ester, amide, or imide-ester with a TAN (oil free) of 3 to 40 mgKOH/g 5-30, 6-20

The dispersant may be present at 20 ppm to 10,000 ppm, 50 ppm to 8000 ppm, 100 ppm to 6000 ppm, 200 ppm to 4000 ppm.

In embodiments, the ratio of dispersant to metal containing detergent can be from 4:1 to 1:2 on a weight basis, or from 3:1 to 1:2, or from 2:1 to 1:2, or from 3:1 to 1:1, or from 2:1 to 1:1.

The heat transfer fluid may also include ashless antioxidants, more specifically sulfur-free antioxidants, such as aminic and/or phenolic antioxidant,

Aminic antioxidants include aromatic amines, such as those of the formula

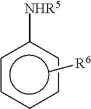

wherein R⁵ can be an aromatic group such as a phenyl group, a naphthyl group, or a phenyl group substituted by R⁷, and R⁶ and R⁷ can be independently a hydrogen or an alkyl group containing 1 to 24 or 4 to 20 or 6 to 12 carbon atoms. In one embodiment, an aromatic amine antioxidant can comprise an alkylated diphenylamine such as nonylated diphenylamine of the formula

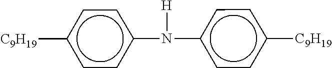

or a mixture of a di-nonylated and a mono-nonylated diphenylamine.

Phenolic antioxidants may be hindered phenolic antioxidants, where one or both ortho-positions on a phenolic ring can be occupied by bulky groups such as t-butyl. Phenolic antioxidants may be of the general the formula

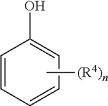

wherein R⁴ is an alkyl group containing 1 to 24, or 4 to 18, carbon atoms and a is an integer of 1 to 5 or 1 to 3, or 2. The phenol may be a butyl substituted phenol containing 2 or 3 t-butyl groups, such as

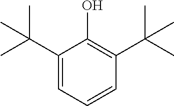

The para position may also be occupied by a hydrocarbyl group or a group bridging two aromatic rings. In certain embodiments the para position can be occupied by an ester-containing group, such as, for example, an antioxidant of the formula

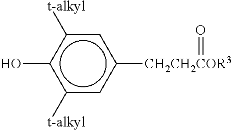

wherein R³ is a hydrocarbyl group such as an alkyl group containing, e.g., 1 to 18 or 2 to 12 or 2 to 8 or 2 to 6 carbon atoms; and t-alkyl can be t-butyl.

In an embodiment, the heat transfer fluid includes an ashless antioxidant. In an embodiment the ashless antioxidant is a sulfur free antioxidant. In an embodiment, the ashless antioxidant is an aminic antioxidant. In an embodiment the ashless antioxidant is a phenolic antioxidant. Mixtures of antioxidants may also be employed.

The total amount of antioxidant can be 0.01 to 5 percent by weight or 0.15 to 4.5 percent or 0.2 to 4 percent or 0.05 to 1 or 0.1 to 0.8 or 0.15 to 0.6 percent by weight of the heat transfer fluid.

The heat transfer fluid may also include a rheology modifier, such as, for example, a high molecular weight polymer. In one embodiment, the polymer may be prepared by polymerizing an alpha-olefin monomer, or mixtures of alpha-olefin monomers, or mixtures comprising ethylene and at least one C3 to C28 alpha-olefin monomer, in the presence of a catalyst system comprising at least one metallocene (e.g., a cyclopentadienyl-transition metal compound) and an alumoxane compound.

Suitable polymers of the olefin polymer variety include ethylene propylene copolymers, ethylene-propylene-alpha olefin terpolymers, ethylene-alpha olefin copolymers, ethylene propylene copolymers further containing a non-conjugated diene, and isobutylene/conjugated diene copolymers, each of which may be subsequently supplied with grafted carboxylic functionality.

Ethylene-propylene or higher alpha monoolefin copolymers may consist of 15 to 80 mole % ethylene and 20 to 85 mole % propylene or higher monoolefin, in some embodiments, the mole ratios being 30 to 80 mole % ethylene and 20 to 70 mole % of at least one C3 to C10 alpha monoolefin, for example, 50 to 80 mole % ethylene and 20 to 50 mole % propylene. Terpolymer variations of the foregoing polymers may contain up to 15 mole % of a non-conjugated diene or triene.

In these embodiments, the polymer substrate, such as the ethylene copolymer or terpolymer, can be an oil-soluble, substantially linear, rubbery material. Also, in certain embodiments the polymer can be in forms other than substantially linear, that is, it can be a branched polymer or a star polymer. The polymer can also be a random copolymer or a block copolymer, including di-blocks and higher blocks, including tapered blocks and a variety of other structures. These types of polymer structures are known in the art and their preparation is within the abilities of the person skilled in the art.

The polymer of the disclosed technology may have a number average molecular weight (by gel permeation chromatography, polystyrene standard), which can typically be 2,000 to 500,000, 10,000 to 300,000, 50,000 to 250,000, or 9,000 to 55,000, or 11,000 to 52,000, or 40,000 to 50,000.

Another useful class of polymers is that constituted by polymers prepared by cationic polymerization of, e.g., isobutene or styrene. Common polymers from this class include polyisobutenes obtained by polymerization of a C4 refinery stream having a butene content of 35 to 75 mass %, and an isobutene content of 30 to 60 mass %, in the presence of a Lewis acid catalyst such as aluminum trichloride or boron trifluoride, aluminum trichloride being suitable. Suitable sources of monomer for making poly-n-butenes are petroleum feed streams such as raffinate II. These feedstocks are disclosed in the art such as in U.S. Pat. No. 4,952,739. Polyisobutylene is a suitable polymer for the present invention because it is readily available by cationic polymerization from butene streams (e.g., using AlCl3 or BF3 catalysts).

It is known that polyisobutylene can be prepared by cationic polymerization with the aid of boron halides, in particular boron trifluoride (E.P.-A 206 756, U.S. Pat. No. 4,316,973, GB-A 525 542, and GB-A 828 367). The polymerization of the isobutylene can be controlled so that polyisobutylenes having number average molecular weights (Mn) far higher than 1,000,000 can be obtained.

In one embodiment the olefin polymer is a copolymer of olefins with 4 or more carbon atoms. In one embodiment, the olefin polymer (polyolefin) comprises 50 to 100% by weight of units derived from at least one olefin monomer having four or more carbon atoms. In typical embodiments the olefins may be unsaturated aliphatic hydrocarbons such as butene, isobutylene (or isobutene), butadiene, isoprene, or combinations thereof.

The polyolefin polymer of the present invention may have a number average molecular weight (by gel permeation chromatography, polystyrene standard) of 20,000 to 10,000,000; 100,000 to 1,500,000; or 200,000 to 1,000,000. In other embodiments the olefin polymer is polyisobutylene with number average molecular weight of at least 50,000, at least 100,000, or at least 250,000 up to 850,000, 600,000, or 500,000. Specific ranges include 250,000 to 750,000 or 250,000 to 500,000.

The polymer can be present on a weight basis in the heat transfer fluid at 0.001 to 1%, or 0.003 to 0.8%, or 0.005 to 0.5%, or 0.01 to 0.1%, or 0.02% to 0.05%, for example 0.003% to 0.1% or even 0.003% to 0.01%. In another embodiment, the polymer additive can be present in the heat transfer fluid at concentrations of no more than 500 ppm (parts per million), or no more than 300 ppm, or no more than 100 ppm, or 10 ppm to 50 ppm, or even 20 to 40 ppm. The concentration of the polymer in the heat transfer fluid is measured on an oil free basis.

Other conventional additives may also be present, for example antioxidants, corrosion inhibitors, fluorelastomer seal reconditioning agents, lubricity additives, flow improvers, or any combination thereof. Supplemental additives may be present in amounts from 0.01 to 2 weight percent, or 0.025 to 2 weight percent, or 0.05 to 1 weight percent, or 0.075 to 0.5 weight percent of the composition.

Various embodiments of the compositions disclosed herein may optionally comprise one or more additional performance additives. These additional performance additives may include one or more flame retardants, smoke suppressants, antioxidants, combustion suppressants, metal deactivators, flow additives, corrosion inhibitors, foam inhibitors, demulsifiers, pour point depressants, seal swelling agents, and any combination or mixture thereof. Typically, fully-formulated heat transfer fluids may contain one or more of these performance additives, and often a package of multiple performance additives. In one embodiment, one or more additional additives may be present at 0.01 weight percent up to 3 weight percent, or 0.05 weight percent up to 1.5 weight percent, or 0.1 weight percent up to 1.0 weight percent.

A thermal management system as disclosed herein may remove heat at a rate that allows for rapid charging of a battery. The target for high-speed charging includes 120 to 1000 kW. The resulting heat generated during battery charging and discharging can result in heat generated in the pack in excess of 10 kw.

A thermal management system as disclosed herein may remove heat at a rate that allows for cooling of a CPU chip or a process node. Operation of a CPU chip can result in heat generated in excess of 350 w from a single chip and up to 2 kW per process node.

A thermal management system as disclosed herein may lubricate a drivetrain, including, for example, a transmission or an electric motor, without associated static discharge.

Heat captured by the fluid may be recaptured and recycled into other functional uses, such as the heating of a building or automobile interior.

As used herein, the term “hydrocarbyl” is used in its ordinary sense, which is well-known to those skilled in the art. Specifically, it refers to a group having a carbon atom directly attached to the remainder of the molecule and having predominantly hydrocarbon character. By “predominantly” it is meant either A) that some amount of the carbon atoms along the groups backbone may be replaced with heteroatoms, for example, every 1 in 5 or 1 in 10 or every 1 in 15 or every 1 in 20, or B) that some amount of the carbon atoms along the groups backbone may be contain side-chains that include heteroatoms, for example, every 1 in 5 or 1 in 10 or every 1 in 15 or every 1 in 20. Examples of hydrocarbyl groups include:
hydrocarbon substituents, that is, aliphatic (e.g., alkyl or alkenyl), alicyclic (e.g., cycloalkyl, cycloalkenyl) substituents, and aromatic-, aliphatic-, and alicyclic-substituted aromatic substituents, as well as cyclic substituents wherein the ring is completed through another portion of the molecule (e.g., two substituents together form a ring);
substituted hydrocarbon substituents, that is, substituents containing non-hydrocarbon groups which, in the context of this invention, do not alter the predominantly hydrocarbon nature of the substituent (e.g., halo (especially chloro and fluoro), hydroxy, alkoxy, mercapto, alkylmercapto, nitro, nitroso, and sulfoxy);
hetero substituents, that is, substituents which, while having a predominantly hydrocarbon character, in the context of this invention, contain other than carbon in a ring or chain otherwise composed of carbon atoms and encompass substituents as pyridyl, furyl, thienyl and imidazolyl. Heteroatoms include sulfur, oxygen, and nitrogen. No more than two, or no more than one, non-hydrocarbon substituent will be present for every ten carbon atoms in the hydrocarbyl group; alternatively, there may be no non-hydrocarbon substituents in the hydrocarbyl group.

It is known that some of the materials described above may interact in the final formulation, so that the components of the final formulation may be different from those that are initially added. For instance, metal ions (of, e.g., a detergent) can migrate to other acidic or anionic sites of other molecules. The products formed thereby, including the products formed upon employing the composition of the present invention in its intended use, may not be susceptible of easy description. Nevertheless, all such modifications and reaction products are included within the scope of the present invention; the present invention encompasses the composition prepared by admixing the components described above.

The invention herein is useful for cooling electrical componentry during operation, which may be better understood with reference to the following examples.

### EXAMPLES

A series of phase change additives were prepared and evaluated for their ability to enhance heat absorption in oil-based fluids. Phase change materials include paraffinic hydrocarbons summarized below (Table 1).

TABLE 1
Paraffinic Hydrocarbons

| ID | IUPAC name | # C Atoms | Melting Point (° C.) |
|---|---|---|---|
| W1 | n- Octacosane | 28 | 61.4 |
| W2 | n-Heptacosane | 27 | 59 |
| W3 | n-Hexacosane | 26 | 56.4 |
| W4 | n-Pentacosane | 25 | 53.7 |
| W5 | n-Tetracosane | 24 | 50.9 |
| W6 | n-Tricosane | 23 | 47.6 |
| W7 | n-Docosane | 22 | 44.4 |
| W8 | n-Heneicosane | 21 | 40.5 |
| W9 | n-Eicosane | 20 | 36.8 |
| W10 | n-Nonadecane | 19 | 32.1 |
| W11 | n-Octadecane | 18 | 28.2 |
| W12 | n-Heptadecane | 17 | 22 |

The paraffinic hydrocarbons are encapsulated within a formaldehyde-coupled melamine resin coating. The encapsulated paraffin wax was acquired from Microtek as MPCM 37D and MPCM 43D. These materials were evaluated as received for thermal properties and were also evaluated for their impact on temperature dependent viscosity (Table 2).

TABLE 2
Encapsulated Paraffin Wax

| | EPW1¹ | EPW2² |
|---|---|---|
| Particle size (mean) (um) | 15-30 | 25-45 |
| Paraffin wax (wt %) | | |
| Melting Point (° C.) | 43 | 57 |
| Heat of Fusion (J/g) | 210 | 180 |
| Kinematic viscosity (KV) at 40° C. of | 44.0 | |
| 2.5 wt % in Oil³ (m²/s) | | |
| KV at 60° C. of 2.5 wt % in Oil (m²/s) | 20.2 | |
| KV at 40° C. of 5 wt % in Oil (m²/s) | 47.1 | |
| KV at 60° C. of 5 wt % in Oil (m²/s) | 22.2 | |
| KV at 40° C. of 10 wt % in Oil (m²/s) | 54.1 | |
| KV at 60° C. of 10 wt % in Oil (m²/s) | 25.8 | |

¹MPCM 43D from Microtek Laboratories Inc.
²nextek 57 from
³Group II base oil with kinematic viscosity at 40° C. of 42.7 m²/s and kinematic viscosity at 60° C. of 19.5 m²/s

Thermal properties of suspensions of phase change material in oil-based thermal fluids was determined through differential scanning calorimetry (DSC). DSC is used to measure heat flow of a sample as a function of temperature. Modulated DSC subjects a sample to a linear heating method which has superimposed sinusoidal temperature oscillation (modulation). The cyclic heating allows separation of the total heat flow into reversible and nonreversible (kinetic) heat flow. The MDSC® analyses for this report were performed on a TA Instruments model Q2000 DSC equipped with RCS90 rapid cooling system. Samples were prepared in an aluminum Tzero™ DSC crucibles with no lid (approximately 6 to 8 mg of sample).

Samples were equilibrated at −60° C. under nitrogen flow. Temperature was modulated plus/minus 0.53° C. every 50 seconds and then ramped 4C per minute up to 75° C. Samples were held at 75° C. for 0.5 minutes and then temperature was ramped at −4° C. per minute until −60° C. was reached. After a 1-minute isothermal hold, the heating temperature cycle was repeated to 80° C.

Formulated thermal fluids were prepared as summarized below (Table 3). In addition to paraffinic hydrocarbon and ether base oils, these fluids contained low treat rates of other performance additives, e.g., organic antioxidants. In addition, fluids included 10 weight percent of dispersed magnesium oxide, added to balance the density of the test fluids with the density of the encapsulated wax particles.

TABLE 3
Thermal Fluids

| | Fluid 1 |
|---|---|
| Oil Composition1 | |
| HC12 | 45 |
| HC23 | 17 |
| Dihexylether | 38 |
| ADDITIVES | |
| Dispersed Magnesium oxide | 10 |
| Di-t-butylphenol | 0.3 |
| Alkylated diphenylamine | 0.075 |
| Calcium sulfonate4 | 0.05 |
| Succinate ester, amine substituted5 | 0.05 |
| Magnesium (wt %) (calculated) | 7.1 |

1Oil formulation normalized to 100%
2Paraffinic hydrocarbon oil with kinematic viscosity at 40° C. of 2.52 m²/g
3Paraffinic hydrocarbon oil with kinematic viscosity at 40° C. of 1.45 m²/g
4Overbased calcium alkylbenzene sulfonate (TBN 300 mg KOH/g; 12 wt % ca; includes 42% oil)
5Ester of N,N-dimethylethanolamine and hexadecyl succinic acid

Encapsulated wax particles were added to the fluid described above. The resulting suspensions were evaluated for phase change behavior by utilizing modulated DSC (Table 4).

TABLE 4
Thermal Phase Change Testing

| | EX1 | EX2 |
|---|---|---|
| Fluid 1 | 95 | 95 |
| EPW1 | | 5 |
| EPW2 | 5 | |
| THERMAL TESTING | | |
| Onset of Phase change Temp (° C.) | 31 | 39.9 |
| Peak of Phase change Temp (° C.) | 39.0 & 57.8 | 44.3 |
| Heat of Fusion [J/g] | 8.1 | 10.7 |

As indicated, both samples displayed an endothermic event consistent with phase change. The magnitude of the heat of fusion was consistent with 5% dilution of the materials in the thermal fluid.

Each of the documents referred to above is incorporated herein by reference, including any prior applications, whether specifically listed above, from which priority is claimed. The mention of any document is not an admission that such document qualifies as prior art or constitutes the general knowledge of the skilled person in any jurisdiction. Except in the Examples, or where otherwise explicitly indicated, all numerical quantities in this description specifying amounts of materials, reaction conditions, molecular weights, number of carbon atoms, and the like, are to be understood as modified by the word “about.” It is to be understood that the upper and lower amount, range, and ratio limits set forth herein may be independently combined. Similarly, the ranges and amounts for each element of the invention can be used together with ranges or amounts for any of the other elements.

As used herein, the transitional term “comprising,” which is synonymous with “including,” “containing,” or “characterized by,” is inclusive or open-ended and does not exclude additional, un-recited elements or method steps. However, in each recitation of “comprising” herein, it is intended that the term also encompass, as alternative embodiments, the phrases “consisting essentially of” and “consisting of,” where “consisting of” excludes any element or step not specified and “consisting essentially of” permits the inclusion of additional un-recited elements or steps that do not materially affect the essential or basic and novel characteristics of the composition or method under consideration.

While certain representative embodiments and details have been shown for the purpose of illustrating the subject invention, it will be apparent to those skilled in this art that various changes and modifications can be made therein without departing from the scope of the subject invention. In this regard, the scope of the invention is to be limited only by the following claims.

What is claimed is:

1. A heat transfer fluid comprising hydrocarbon oil and heat transfer additive, wherein the heat transfer additive comprises phase change material.

2. The heat transfer fluid of claim 1, wherein the phase change material is present from 1 to 50 wt. %.

3. The heat transfer fluid of claim 1, wherein the phase change material comprises paraffinic hydrocarbon having a melting temperature between 3° and 60° C.

4. The heat transfer fluid of claim 1, wherein the phase change material comprises carboxylic acids having a melting temperature between 30 and 60° C.

5. The heat transfer fluid of claim 1, wherein the phase change material comprises a phenol or fatty alcohol having a melting temperature between 3° and 60° C.

6. The heat transfer fluid of claim 1, wherein the phase change material comprises polymer materials having a melting temperature between 3° and 60° C.

7. The heat transfer fluid of claim 1, wherein the phase change material is encapsulated by an encapsulant comprising surfactant.

8. The heat transfer fluid of claim 1, wherein the phase change material is encapsulated by an encapsulant comprising polymer shell.

9. The heat transfer fluid of claim 1, wherein the phase change material is encapsulated by an encapsulant comprising metal oxide shell.

10. The heat transfer fluid of claim 1, wherein the heat transfer additive further comprises a halogenated hydrocarbon.

11. The heat transfer fluid of claim 9, wherein the boiling point of the halogenated hydrocarbon is between from 5% lower to equivalent to the flash point of the hydrocarbon oil.

12. The heat transfer fluid of claim 9, wherein the halogenated hydrocarbon comprises fluorocarbon.

13. The heat transfer fluid of claim 9, wherein the halogenated hydrocarbon is present from 0.1 to 25 wt. %.

14. A method of lubricating an electrified driveline comprising applying to said driveline the heat transfer fluid of claim 1.

15. A method of cooling electrical componentry comprising immersing the electrical componentry in a bath comprising a heat transfer fluid of claim 1 and operating the electrical componentry.

16. The method of claim 15, wherein the electrical componentry is a battery pack.

17. The method of claim 15, wherein the electrical componentry is a computer server.

18. An immersion coolant system comprising electrical componentry situated in a bath, wherein the bath is in fluid contact with a heat transfer fluid reservoir comprising the heat transfer fluid of claim 1.

19. The system of claim 18, wherein the electrical componentry is a battery pack.

20. The system of claim 18, wherein the electrical componentry is a computer server.
